(19) United States
(12) Patent Application Publication
(10) Pub. No.: US 2024/0164094 A1
(43) Pub. Date: May 16, 2024

(54) SEMICONDUCTOR MEMORY DEVICES AND ELECTRONIC SYSTEMS INCLUDING THE SAME

(71) Applicant: SAMSUNG ELECTRONICS CO., LTD., Suwon-si (KR)

(72) Inventors: Ji-Sung KIM, Suwon-si (KR); Jung Min PARK, Suwon-si (KR); Bong Jin KUH, Suwon-si (KR); Yong Ho HA, Suwon-si (KR)

(21) Appl. No.: 18/479,591

(22) Filed: Oct. 2, 2023

(30) Foreign Application Priority Data
Nov. 11, 2022 (KR) 10-2022-0150252

(51) Int. Cl. H10B 41/27; H01L 21/28; H01L 25/065; H01L 29/51; H10B 41/10; H10B 41/35; H10B 43/10; H10B 43/27; H10B 43/35; H10B 80/00

(52) U.S. Cl. CPC H10B 41/27; H01L 25/0652; H01L 29/40111; H01L 29/516; H10B 41/10; H10B 41/35; H10B 43/10; H10B 43/27; H10B 43/35; H10B 80/00; H01L 2225/06506

(57) ABSTRACT

A semiconductor memory device comprises, a substrate, a mold structure including gate electrodes and mold insulating films alternately stacked on the substrate, and a channel structure penetrating the mold structure, wherein the channel structure comprises a semiconductor pattern and a dielectric film on the semiconductor pattern, wherein the dielectric film comprises a first crystalline film in contact with the gate electrodes and a second crystalline film between the first crystalline film and the semiconductor pattern, wherein the first crystalline film includes a first matrix and a first impurity and the second crystalline film includes a second matrix and a second impurity, wherein each of the first matrix and the second matrix comprises at least one of HfO₂, HfₓZr₁₋ₓO₂ (0.5<x<1) and Hf_{1-y}Zr_{y}O² (0.5<y<1), and wherein each of the first impurity and the second impurity is 10 at % or less of the first crystalline film and second crystalline film, respectively.

### CROSS-REFERENCE TO RELATED APPLICATION

This application claims priority to Korean Patent Application No. 10-2022-0150252 filed on Nov. 11, 2022 in the Korean Intellectual Property Office, and all the benefits accruing therefrom under 35 U.S.C. 119, the contents of which in its entirety are herein incorporated by reference.

### BACKGROUND

The present disclosure relates to semiconductor memory devices and electronic systems including the same. More particularly, the present disclosure relates to three-dimensional semiconductor memory devices including three-dimensionally arranged memory cells and electronic systems including the same.

Semiconductor memory devices are becoming more highly integrated to meet consumer demand for high performance and affordable electronic devices. That is, the degree of integration of a semiconductor device is an important factor for determining its price. Therefore, the degree of integration of semiconductor memory devices must be increased to keep costs down.

The degree of integration of a typical two-dimensional or planar semiconductor memory device is mainly determined by the area that a unit memory cell of such a device occupies. The ability to scale down the area of a unit memory cell depends on the level of sophistication of techniques for forming fine patterns of features that make up the memory cells. In this respect, high-priced diverse pieces of equipment are required for forming fine patterns. Therefore, there are limitations in the cost savings that can be obtained when increasing the degree of integration of a two-dimensional semiconductor memory device. Thus, three-dimensional semiconductor memory devices having three-dimensionally arranged memory cells have been developed.

### SUMMARY

Aspects of the present disclosure provide semiconductor memory devices capable of improving durability and reliability.

Aspects of the present disclosure also provide electronic systems including semiconductor memory devices capable of improving durability and reliability.

However, aspects of the present disclosure are not restricted to those set forth herein. The above and other aspects of the present disclosure may be more clearly understood by referencing the detailed description of the present disclosure given below.

According to an aspect of the present disclosure, there is provided a semiconductor memory device comprising, a substrate, a mold structure including a plurality of gate electrodes and a plurality of mold insulating films alternately stacked on the substrate and a channel structure that penetrates the mold structure, wherein the channel structure comprises a semiconductor pattern and a dielectric film on the semiconductor pattern, wherein the dielectric film comprises a first crystalline film that is in contact with the plurality of gate electrodes and a second crystalline film between the first crystalline film and the semiconductor pattern, wherein the first crystalline film includes a first matrix and a first impurity, wherein the second crystalline film includes a second matrix and a second impurity, wherein each of the first matrix and the second matrix comprises at least one of HfO₂, HfₓZr₁₋ₓO₂ (0.5<x<1) and Hf_{1-y}Zr_{y}O₂ (0.5<y<1), and wherein each of the first impurity and the second impurity has a concentration of 10 at % (atomic percent) or less of the first crystalline film and the second crystalline film, respectively.

According to some aspects of the present disclosure, there is provided a semiconductor memory device comprising, a substrate, a mold structure including a plurality of gate electrodes and a plurality of mold insulating films alternately stacked on the substrate and a channel structure that penetrates the mold structure, wherein the channel structure comprises a semiconductor pattern, an interfacial film on the semiconductor pattern, a first crystalline film on the interfacial film, a second crystalline film on the first crystalline film and in contact with the plurality of gate electrodes, and an amorphous film between the first crystalline film and the second crystalline film, wherein the interfacial film is between the semiconductor pattern and the first crystalline film, wherein the first crystalline film is between the second crystalline film and the semiconductor pattern, wherein the amorphous film comprises a first material, wherein a first matrix of the amorphous film comprises HfO₂ and ZrO₂, and wherein the first material comprises Al₂O₃ and/or SiO₂.

According to some aspects of the present disclosure, there is provided an electronic system comprising, a main board, a semiconductor memory device on the main board; and a controller on the main board, wherein the controller is electrically connected to the semiconductor memory device, wherein the semiconductor memory device comprises a cell substrate comprising a cell array region and an extension region, a mold structure comprising a plurality of gate electrodes that are sequentially stacked on the cell substrate and stacked in the extension region in a stepped manner, and a channel structure that penetrates the mold structure in the cell array region, wherein the channel structure comprises a semiconductor pattern and a dielectric film on the semiconductor pattern, wherein the dielectric film comprises a first crystalline film and a second crystalline film between the first crystalline film and the semiconductor pattern, wherein the first crystalline film is in contact with the plurality of gate electrodes, wherein the first crystalline film includes a first matrix and the second crystalline film includes a second matrix, wherein each of the first matrix and the second matrix comprises at least one of HfO₂, HfₓZr₁₋ₓO₂ (0.5<x<1) and Hf_{1-y}Zr_{y}O₂ (0.5<y<1), wherein the first crystalline film has 10 at % (atomic percent) or less of a first impurity, wherein the second crystalline film has 10 at % or less of a second impurity, and wherein each of the first impurity and the second impurity comprises Al2O3, SiO2, Y2O3, Er2O3, Lu2O3, Gd2O3, Ta₂O₅, MgO, SiC, AlN, and/or Mo.

It should be noted that the effects of the present disclosure are not limited to those described above, and other effects of the present disclosure may be more clearly understood from the following description.

### BRIEF DESCRIPTION OF THE DRAWINGS

The above and other aspects and features of the present disclosure may be more clearly understood by describing in detail example embodiments thereof with reference to the attached drawings, in which:

FIG. 1 is an example block diagram illustrating a semiconductor memory device according to some embodiments.

FIG. 2 is an exemplary circuit diagram illustrating a semiconductor memory device according to some embodiments.

FIG. 3 is an example plan view layout diagram illustrating a semiconductor memory device according to some embodiments.

FIG. 4 is a cross-sectional view taken along line A-A′ of FIG. 3.

FIG. 5 is an enlarged view illustrating portion R1 of FIG. 4.

FIG. 6 is an enlarged view illustrating portion R2 of FIG. 5.

FIG. 7 is a cross-sectional view taken along line B-B′ of FIG. 3.

FIGS. 8 and 9 are graphs for explaining a dielectric film of a semiconductor memory device according to some embodiments.

FIG. 10 is a graph for explaining a semiconductor memory device according to some embodiments.

FIG. 11 is a view for explaining a semiconductor memory device according to some embodiments.

FIG. 12 is a view for explaining a semiconductor memory device according to some embodiments.

FIG. 13 is a view for explaining a semiconductor memory device according to some embodiments.

FIG. 14 is a view for explaining a semiconductor memory device according to some embodiments.

FIG. 15 is a view for explaining a semiconductor memory device according to some embodiments.

FIG. 16 is an example block diagram illustrating an electronic system according to some embodiments.

FIG. 17 is an example perspective view illustrating an electronic system according to some embodiments.

FIG. 18 is a schematic cross-sectional view taken along line I-I′ of FIG. 17 and an enlarged view of a portion thereof.

### DETAILED DESCRIPTION OF THE EMBODIMENTS

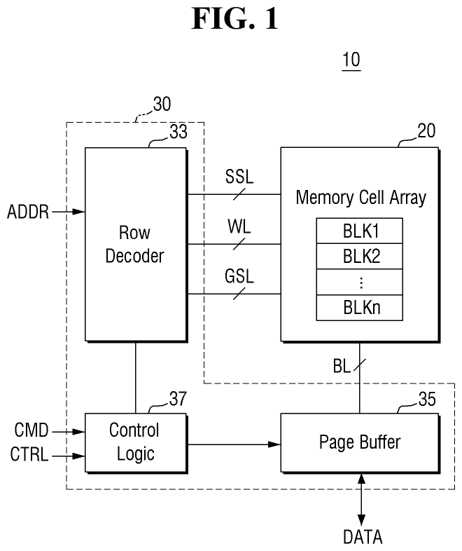

Hereinafter, a semiconductor memory device according to example embodiments will be described with reference to FIGS. 1 to 10.

FIG. 1 is an example block diagram illustrating a semiconductor memory device according to some embodiments.

Referring to FIG. 1, a semiconductor memory device 10 according to some embodiments may include a memory cell array 20 and a peripheral circuit 30.

The memory cell array 20 may include a plurality of memory cell blocks BLK1 to BLKn. Each of the plurality of memory cell blocks BLK1 to BLKn may include a plurality of memory cells. The memory cell array 20 may be connected (e.g., electrically connected) to the peripheral circuit 30 through a bit line BL, a word line WL, a string selection line SSL, and a ground selection line GSL. For example, the plurality of memory cell blocks BLK1 to BLKn may be connected (e.g., electrically connected) to a row decoder 33 through the word line WL, the string select line SSL, and the ground selection line GSL. Also, for example, the plurality of memory cell blocks BLK1 to BLKn may be connected (e.g., electrically connected) to a page buffer 35 through the bit line BL.

The peripheral circuit 30 may receive an address ADDR, a command CMD, and a control signal CTRL from the outside of the semiconductor memory device 10 (e.g., an external circuit), and may transmit and receive data DATA to and from a device outside the semiconductor memory device 10. The device outside the semiconductor memory device 10 and the external circuit of the semiconductor memory device 10 may refer to a same circuit, device, or system, but is not limited thereto. The peripheral circuit 30 may include a control logic 37, the row decoder 33, and the page buffer 35. Although not shown, the peripheral circuit 30 may further include various sub-circuits such as an input/output circuit, a voltage generating circuit generating various voltages required for operation of the semiconductor memory device 10, and an error correction circuit for correcting data read from the memory cell array 20. However, the embodiments of the peripheral circuit 30 are not limited thereto.

The control logic 37 may be connected (e.g., electrically connected) to the row decoder 33, the input/output circuit, and the voltage generating circuit. The control logic 37 may control the overall operation of the semiconductor memory device 10. The control logic 37 may generate various internal control signals used in the semiconductor memory device 10 in response to the control signal CTRL. For example, the control logic 37 may adjust a voltage level provided to the word lines WL and the bit lines BL during a memory operation, such as a program operation or an erase operation.

The row decoder 33 may select at least one of the plurality of memory cell blocks BLK1 to BLKn in response to the address ADDR, and may select at least one of the word lines WL, at least one of the string selection lines SSL, and at least one of the ground selection lines GSL of the selected memory cell block. Also, the row decoder 33 may transfer a voltage for performing a memory operation to the selected word line WL of the selected memory cell block.

The page buffer 35 may be connected (e.g., electrically connected) to the memory cell array 20 via the bit line BL. The page buffer 35 may operate as a writer driver or a sense amplifier. For example, during a program operation, the page buffer 35 may operate as a write driver and apply to the bit line BL a voltage according to data DATA to be stored in the memory cell array 20. During a read operation, the page buffer 35 may operate as a sense amplifier and sense the data DATA stored in the memory cell array 20.

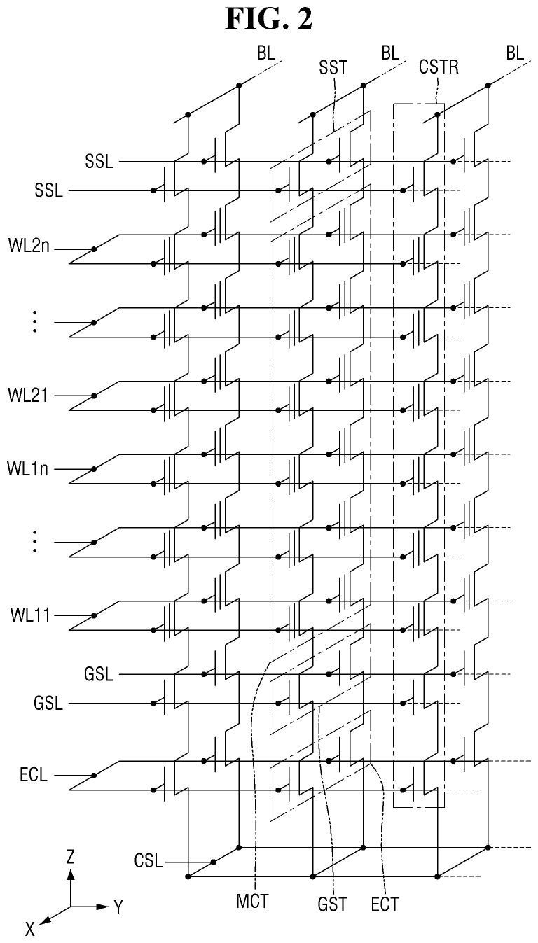

FIG. 2 is an example circuit diagram illustrating a semiconductor memory device according to some embodiments.

Referring to FIG. 2, a memory cell array (e.g., memory cell array 20 of FIG. 1) of a semiconductor memory device according to some embodiments may include a common source line CSL, the bit line BL, and a plurality of cell strings CSTR.

The common source line CSL may extend in a first direction X. In some embodiments, a plurality of common source lines CSL may be two-dimensionally arranged. For example, the plurality of common source lines CSL may be spaced apart from each other, each extending in the first direction X. The same voltage may be applied to the plurality of common source lines CSL. Alternatively, the plurality of common source lines CSL may be controlled independently of each other by a different voltage applied thereto.

In some embodiments, a plurality of bit lines BL may be two-dimensionally arranged. For example, the plurality of bit lines BL may be spaced apart from each other, each extending in a second direction Y intersecting the first direction X. The plurality of respective cell strings CSTR may be connected (e.g., electrically connected) in parallel to each of the plurality of bit lines BL. The plurality of cell strings CSTR may be connected (e.g., electrically connected) in common to the common source line CSL. That is, the plurality of cell strings CSTR may be disposed between the bit line BL and the common source line CSL.

Each of the plurality of cell strings CSTR may include a ground selection transistor GST connected (e.g., electrically) to the common source line CSL, a string selection transistor SST connected (e.g., electrically) to the bit line BL, and a plurality of memory cell transistors MCT disposed between the ground selection transistor GST and the string selection transistor SST. Each of the plurality of memory cell transistors MCT may include a data storage element. The ground selection transistor GST, the string selection transistor SST, and the plurality of memory cell transistors MCT may be connected (e.g., electrically connected) in series.

The common source line CSL may be connected (e.g., electrically connected) in common to sources of the ground selection transistors GST. In addition, a ground selection line GSL, a plurality of word lines WL11 to WL1n and WL21 to WL2n, and a string selection line SSL may be disposed between the common source line CSL and the bit line BL. The ground selection line GSL may be used as a gate electrode of the ground selection transistor GST, the plurality of word lines WL11 to WL1n and WL21 to WL2n may be used as gate electrodes of the plurality of memory cell transistors MCT, and the string selection line SSL may be used as a gate electrode of the string selection transistor SST.

In some embodiments, an erase control transistor ECT may be disposed between the common source line CSL and the ground selection transistor GST. The common source line CSL may be connected (e.g., electrically connected) in common to the erase control transistors ECT. Also, an erase control line ECL may be disposed between the common source line CSL and the ground selection line GSL. The erase control line ECL may be used as a gate electrode of the erase control transistor ECT. The erase control transistors ECT may generate a gate induced drain leakage (GIDL) to execute the erase operation of the memory cell array.

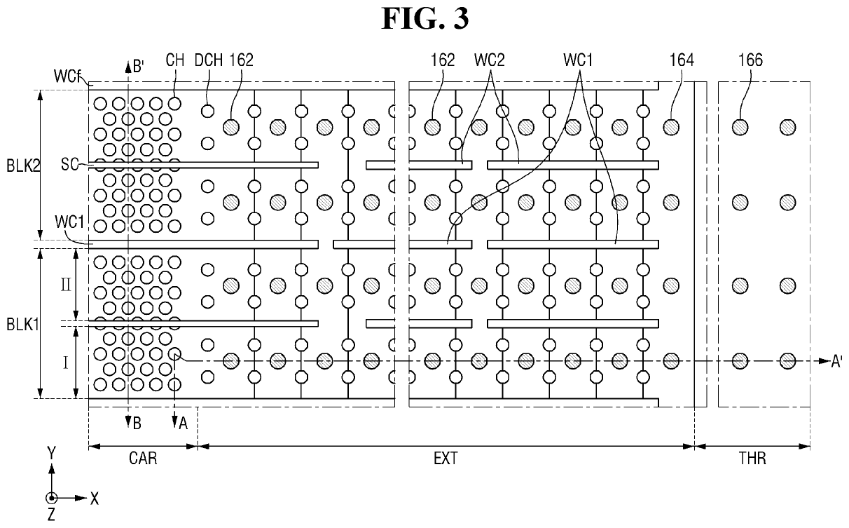

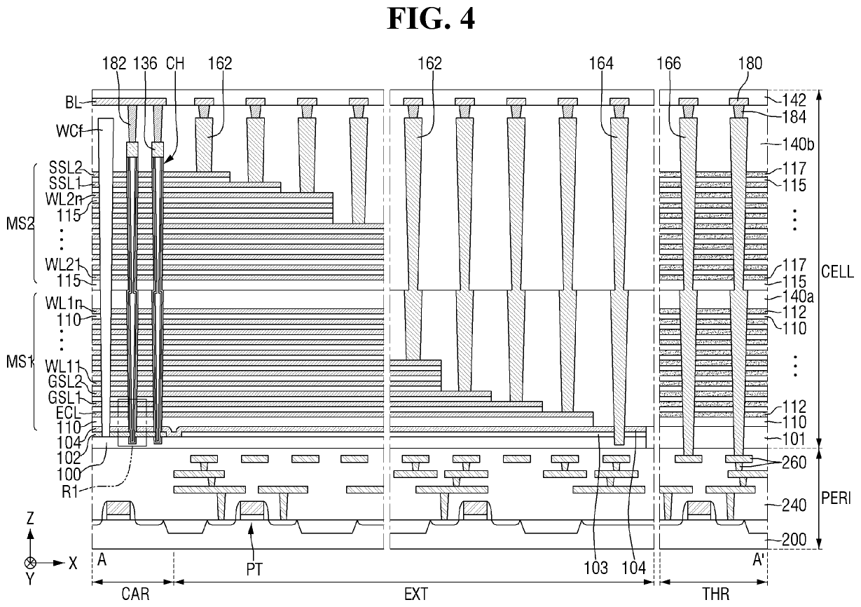

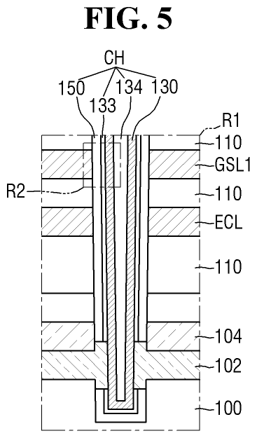

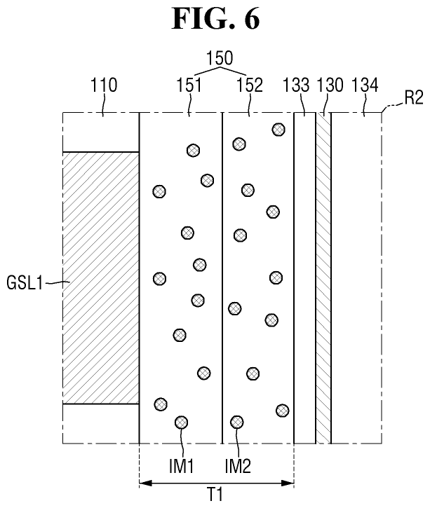

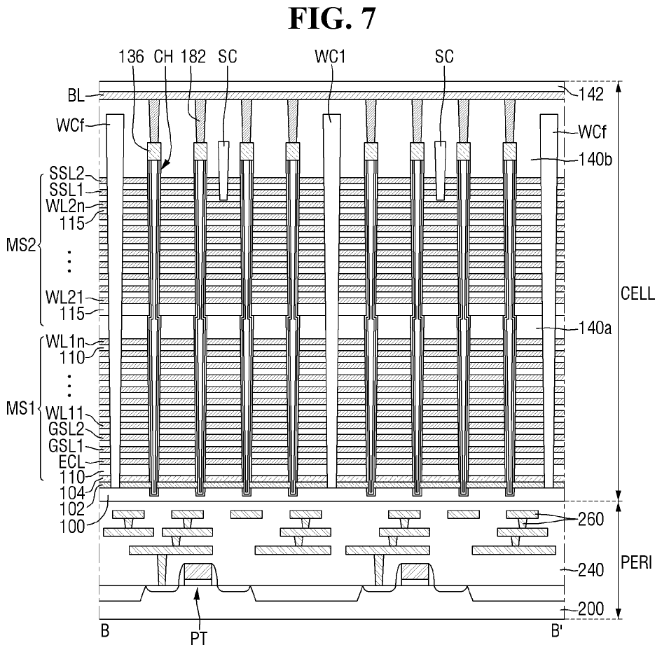

FIG. 3 is an example plan view layout diagram illustrating a semiconductor memory device according to some embodiments. FIG. 4 is a cross-sectional view taken along line A-A′ of FIG. 3. FIG. 5 is an enlarged view illustrating portion R1 of FIG. 4. FIG. 6 is an enlarged view illustrating portion R2 of FIG. 5. FIG. 7 is a cross-sectional view taken along line B-B′ of FIG. 3.

Referring to FIGS. 3 to 7, a semiconductor memory device according to some embodiments may include a memory cell region CELL and a peripheral circuit region PERI.

The memory cell region CELL may include a cell substrate 100, an insulating substrate 101, mold structures MS1 and MS2, interlayer insulating films 140a and 140b, channel structures CH, block isolation regions WCf, first partial isolation regions WC1, second partial isolation regions WC2, string isolation structures SC, bit lines BL, cell contacts 162, source contacts 164, through vias 166, and first wiring structures 180.

The cell substrate 100 may include, as non-limiting examples, a semiconductor substrate such as a silicon substrate, a germanium substrate, or a silicon-germanium substrate. In some embodiments, the cell substrate 100 may include a silicon-on-insulator (SOI) substrate, a germanium-on-insulator (GOI) substrate, or the like. In some embodiments, the cell substrate 100 may include impurities. For example, the cell substrate 100 may include n-type impurities (e.g., phosphorus (P), arsenic (As), etc.), but is not limited thereto.

The cell substrate 100 may include a cell array region CAR and an extension region EXT.

A memory cell array (e.g., memory cell array 20 of FIG. 1) including a plurality of memory cells may be formed in the cell array region CAR. For example, a channel structure CH, a bit line BL, gate electrodes ECL (e.g., erase control line ECL in FIG. 2), GSL1, GSL2 (e.g., ground selection line GSL in FIG. 2), WL11 to WL1n, WL21 to WL2n (e.g., plurality of word lines WL11 to WL1n and WL21 to WL2n in FIG. 2), SSL1, and SSL2 (e.g., string selection line SSL in FIG. 2) and the like may be disposed in the cell array region CAR, as explained herein. In the following description, a surface of the cell substrate 100 on which the memory cell array is disposed may be referred to as a front side of the cell substrate 100. A surface of the cell substrate 100 opposite to the front side of the cell substrate 100 may be referred to as a back side of the cell substrate 100.

The extension region EXT may be disposed around the cell array region CAR. The gate electrodes ECL, GSL1, GSL2, WL11 to WL1n, WL21 to WL2n, SSL1, and SSL2, as explained herein, may be stacked in the extension region EXT in a stepped manner. The stepped manner means that the gate electrodes ECL, GSL1, GSL2, WL11 to WL1n, WL21 to WL2n, SSL1, and SSL2 may have a smaller size as a distance in a perpendicular direction (e.g., a third direction Z) from an upper surface of the cell substrate 100 increases. For example, in a plan view the gate electrodes ECL, GSL1, GSL2, WL11 to WL n, WL21 to WL2n, SSL1, and SSL2 may have a smaller length in the first direction X and/or in the second direction Y as the distance in the third direction Z from the upper surface of the cell substrate 100 increases.

In some embodiments, the cell substrate 100 may further include a through region THR. The through region THR may be disposed inside the cell array region CAR, or may be disposed outside the cell array region CAR and the extension region EXT. For example, the through region THR may be disposed around the extension region Ext. A through via 166, as explained herein, may be disposed in the through region THR.

The insulating substrate 101 may be formed in the cell substrate 100 in the extension region EXT. The insulating substrate 101 may form an insulating region in the cell substrate 100 of the extension region EXT. The insulating substrate 101 may include, for example, silicon oxide, silicon nitride, silicon oxynitride, or silicon carbide, but is not limited thereto. In some embodiments, the insulating substrate 101 may be formed in the cell substrate 100 of the through region THR.

Although a lower surface of the insulating substrate 101 is shown as being coplanar with a lower surface of the cell substrate 100, this is only an example. In some examples, the lower surface of the insulating substrate 101 may be lower than the lower surface of the cell substrate 100.

The mold structures MS1 and MS2 may be formed on the front side of the cell substrate 100. The mold structures MS1 and MS2 may include a plurality of gate electrodes ECL, GSL1, GSL2, WL11 to WL1n, WL21 to WL2n, SSL1, and SSL2 and a plurality of mold insulating films 110 and 115 stacked on the cell substrate 100. The gate electrodes ECL, GSL1, GSL2, WL11 to WL1n, WL21 to WL2n, SSL1, and SSL2 and the mold insulating films 110 and 115 may form a stratified structure extending parallel to the front side of the cell substrate 100. The gate electrodes ECL, GSL1, GSL2, WL11 to WL1n, WL21 to WL2n, SSL1, and SSL2 may be sequentially stacked on the cell substrate 100 while being spaced apart from one another by the mold insulating films 110 and/or 115.

In some embodiments, the mold structures MS1 and MS2 may include a first mold structure MS1 and a second mold structure MS2 sequentially stacked on the cell substrate 100.

The first mold structure MS1 may include first gate electrodes ECL, GSL1, GSL2, and WL11 to WL1n that are alternately stacked on the cell substrate 100 with the first mold insulating films 110. In some embodiments, the first gate electrodes ECL, GSL1, GSL2, and WL11 to WLIn may include an erase control line ECL, ground selection lines GSL1 and GLS2, and a plurality of first word lines WL11 to WL1n sequentially stacked on the cell substrate 100. The ground selection lines GSL1 and GSL2 may include a first ground selection line GSL1 and a second ground selection line GSL2 sequentially stacked. Although the first gate electrodes ECL, GSL1, GSL2, and WL11 to WL1n are shown as including two ground selection lines GSL1 and GSL2, this is merely an example. The first gate electrodes ECL, GSL1, GSL2, and WL11 to WL1n may include three or more ground selection lines. In some embodiments, the erase control line ECL may be omitted.

The second mold structure MS2 may include second gate electrodes WL21 to WL2n, SSL1, and SSL2 that are alternately stacked on the first mold structure MS1 with the second mold insulating films 115. In some embodiments, the second gate electrodes WL21 to WL2n, SSL1, and SSL2 may include a plurality of second word lines WL21 to WL2n and the string selection lines SSL and SSL2 sequentially stacked on the first mold structure MS1. The string selection lines SSL1 and SSL2 may include a first string selection line SSL1 and a second string selection line SSL2 sequentially stacked. Although the second gate electrodes WL21 to WL2n, SSL1, and SSL2 are shown as including two string selection lines SSL1 and SSL2, this is merely an example. The second gate electrodes WL21 to WL2n, SSL1, and SSL2 may include three or more string selection lines.

The gate electrodes ECL, GSL1, GSL2, WL11 to WL1n, WL21 to WL2n, SSL1, and SSL2 may be each made of a conductive material, for example, metal such as tungsten (W), cobalt (Co), or nickel (Ni), or a semiconductor material such as silicon, but is not limited thereto.

Each of the mold insulating films 110 and 115 may include an insulating material, for example, silicon oxide, silicon nitride, and/or silicon oxynitride, but is not limited thereto.

In some embodiments, the mold structures MS1 and MS2 of the through region THR may include a plurality of mold sacrificial films 112 and 117 that are alternately stacked on the cell substrate 100 and/or the insulating substrate 101 with the plurality of mold insulating films 110 and 115. The mold sacrificial films 112 and 117 and the mold insulating films 110 and 115 may form a stratified structure extending parallel to an upper surface of the cell substrate 100. The mold sacrificial films 112 and 117 may be sequentially stacked on the cell substrate 100 while being spaced apart from each other by the mold insulating films 110 and/or 115.

In some embodiments, the first mold structure MS1 of the through region THR may include first mold sacrificial films 112 that are alternately stacked on the cell substrate 100 with the first mold insulating films 110. The second mold structure MS2 of the through region THR may include second mold sacrificial films 117 that are alternately stacked on the first mold structure MS1 with the second mold insulating films 115.

Each of the mold sacrificial films 112 and 117 may include an insulating material, for example, silicon oxide, silicon nitride, and/or silicon oxynitride, but is not limited thereto. In some embodiments, the mold sacrificial films 112 and 117 may include a material having an etch selectivity with respect to the mold insulating films 110 and 115. For example, the mold insulating films 110 and 115 may include silicon oxide and the mold sacrificial films 112 and 117 may include silicon nitride.

The interlayer insulating films 140a and 140b may be formed on the cell substrate 100 to cover a portion (e.g., upper surface) of each of the mold structures MS1 and MS2. In some embodiments, the interlayer insulating films 140a and 140b may include a first interlayer insulating film 140a and a second interlayer insulating film 140b sequentially stacked on the cell substrate 100. The first interlayer insulating film 140a may cover a portion (e.g., upper surface) of the first mold structure MS1 and the second interlayer insulating film 140b may cover a portion (e.g., upper surface) of the second mold structure MS2. The interlayer insulating films 140a and 140b may include, for example, silicon oxide, silicon oxynitride, and/or a low-k material having a dielectric constant lower than silicon oxide, but is not limited thereto.

The channel structures CH may be formed in the mold structures MS1 and MS2 of the cell array region CAR. The channel structures CH may extend in a perpendicular direction (the third direction Z) intersecting the upper surface of the cell substrate 100 and penetrate the mold structures MS1 and MS2. For example, the channel structures CH may be in a pillar shape (e.g., a cylindrical shape) extending in the third direction Z, but the embodiments of the channel structures CH are not limited thereto. Accordingly, the channel structures CH may intersect each of the gate electrodes ECL, GSL1, GSL2, WL11 to WL1n, WL21 to WL2n, SSL1, and SSL2. In some embodiments, each of the channel structures CH may have a bent portion between the first mold structure MS1 and the second mold structure MS2.

As shown in FIGS. 4 and 5, the channel structure CH may include a semiconductor pattern 130, an interfacial film 133, and a dielectric film 150.

The semiconductor pattern 130 may extend in the third direction Z and penetrate the mold structures MS1 and MS2. The semiconductor pattern 130 is illustrated as being in a cup shape but this is merely an example. The semiconductor pattern 130 may have various shapes such as a cylindrical shape, a square cylinder shape, or a non-hollow pillar shape, but is not limited thereto. The semiconductor pattern 130 may include a semiconductor material such as monocrystalline silicon, polycrystalline silicon, an organic semiconductor material, or a carbon nanostructure, but is not limited thereto.

The interfacial film 133 may be disposed on the semiconductor pattern 130. The interfacial film 133 may be interposed between the semiconductor pattern 130 and each of the gate electrodes ECL, GSL1, GSL2, WL11 to WL1n, WL21 to WL2n, SSL1, and SSL2. For example, the interfacial film 133 may extend along outer side surfaces of the semiconductor pattern 130. The interfacial film 133 may include, for example, silicon oxide (e.g., SiO₂) or a high-k material (e.g., aluminum oxide (Al₂O₃)) having a dielectric constant higher than silicon oxide.

Referring to FIG. 6, the dielectric film 150 may be disposed on the interfacial film 133. The dielectric film 150 may be in contact with each of the gate electrodes ECL, GSL1, GSL2, WL11 to WL1n, WL21 to WL2n, SSL1, and SSL2. For example, the dielectric film 150 may extend along outer side surfaces of the interfacial film 133. The dielectric film 150 may include a first crystalline film 151 and a second crystalline film 152. Although the dielectric film 150 is illustrated as including two films, but the present disclosure is not limited to this case. For example, the dielectric film 150 may include a plurality of films. A thickness T1 of the dielectric film 150 may be 150 angstroms or less. Here, the thickness T1 of the dielectric film 150 may be a thickness in the first direction X or the second direction Y.

The first crystalline film 151 (e.g., outmost film in the dielectric film 150) may be in contact with each of the gate electrodes ECL, GSL1, GSL2, WL11 to WLin, WL21 to WL2n, SSL1, and SSL2 and each of the mold insulating films 110 and 115. The first crystalline film 151 may be interposed between the interfacial film 133 and each of the gate electrodes ECL, GSL1, GSL2, WL11 to WL1n, WL21 to WL2n, SSL1, and SSL2.

The first crystalline film 151 may include hafnium-based oxide. In one embodiment, a first matrix of the first crystalline film 151 may include hafnium oxide (HfO₂), hafnium zirconium oxide (HfₓZr₁₋ₓO₂ (0.5<x<1)), and/or hafnium zirconium oxide (Hf_{1-y}Zr_{y}O₂ (0.5<y<1)). However, the present disclosure is not limited to this case. In some embodiments, the first crystalline film 151 may include zirconium oxide (ZrO), tantalum oxide (TaO), or vanadium oxide (VO₂). The above-noted materials of the first crystalline film 151 may be the first matrix of the first crystalline film 151. The first crystalline film 151 may include the first matrix and a first impurity IM1.

The first impurity IM1 may include a material having a Young's modulus of 150 Gpa (gigapascal) or more, a material having a shear modulus of 100 Gpa or more, and/or a material having a thermal expansion coefficient of 5.0×10E-6/k or less. The first impurity IM1 may include, for example, aluminum oxide (Al₂O₃), silicon oxide (SiO₂), yttrium oxide (Y₂O₃), erbium oxide (Er₂O₃), lutetium oxide (Lu₂O₃), gadolinium oxide (Gd₂O₃), tantalum oxide (Ta₂O₅), magnesium oxide (MgO), silicon carbide (SiC), aluminum nitride (AlN), and/or molybdenum (Mo), but is not limited thereto. The concentration of the first impurity IM1 may be 10 at % (atomic percent) or less of the first crystalline film 151.

The second crystalline film 152 may be disposed on the first crystalline film 151. The second crystalline film 152 may be interposed between the first crystalline film 151 and the interfacial film 133. The second crystalline film 152 may extend along outer side surfaces of the interfacial film 133.

The second crystalline film 152 may include a second impurity IM2. The second crystalline film 152 may include hafnium-based oxide. In one embodiment, a second matrix of the second crystalline film 152 may include hafnium oxide (HfO₂), hafnium zirconium oxide (HfₓZr₁₋ₓO₂ (0.5<x<1)), and/or hafnium zirconium oxide (Hf_{1-y}Zr_{y}O₂ (0.5<y<1)). However, the present disclosure is not limited to this case. In some embodiments, the second crystalline film 152 may include zirconium oxide, tantalum oxide, or vanadium oxide. As in the first crystalline film 151, the above-noted materials of the second crystalline film 152 may be the second matrix of the second crystalline film 152. The second crystalline film 152 may include the second matrix and the second impurity IM2.

The second impurity IM2 may include, for example, a material having a Young's modulus of 150 Gpa or more, a material having a shear modulus of 100 Gpa or more, and/or a material having a thermal expansion coefficient of 5.0×10E-6/k or less, but is not limited thereto. The second impurity IM2 may include, for example, aluminum oxide, silicon oxide, yttrium oxide, erbium oxide, lutetium oxide, gadolinium oxide, tantalum oxide, magnesium oxide, silicon carbide, aluminum nitride, and/or molybdenum, but is not limited thereto. The concentration of the second impurity IM2 may be 10 at % (atomic percent) or less of the second crystalline film 152.

In some embodiments, the first matrix of the first crystalline film 151 may include the same material as the second matrix of the second crystalline film 152. In this case, the first impurity IM1 of the first crystalline film 151 may include a different material from the second impurity IM2 of the second crystalline film 152.

In some embodiments, the first impurity IM1 of the first crystalline film 151 may include the same material as the second impurity IM2 of the second crystalline film 152. In this case, the first matrix of the first crystalline film 151 may include a different material from the second matrix of the second crystalline film 152.

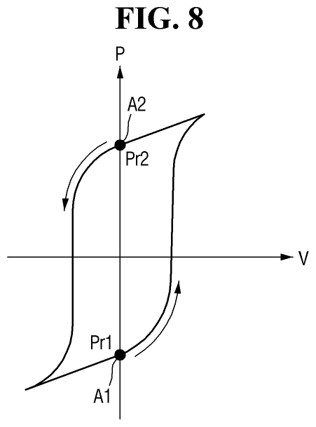

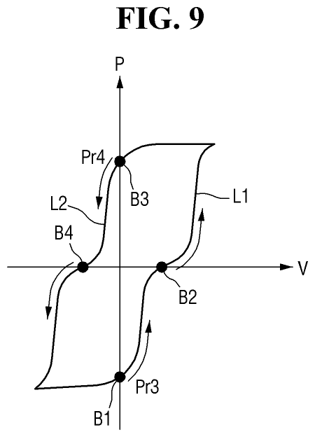

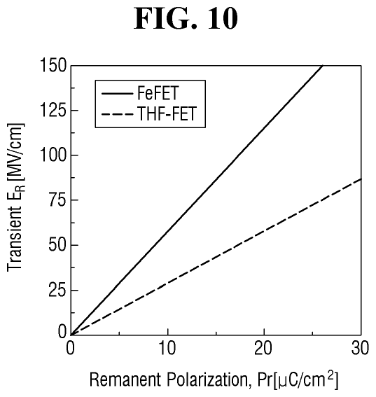

FIGS. 8 and 9 are graphs for explaining a dielectric film of a semiconductor memory device according to some embodiments. FIG. 10 is a graph for explaining a semiconductor memory device according to some embodiments. Specifically, FIG. 8 shows a polarization-hysteresis curve of a ferroelectric material and FIG. 9 shows a polarization-hysteresis curve of the dielectric film 150 of the semiconductor memory device of FIG. 4.

Referring to FIG. 8, a ferroelectric material may have a variable polarization value along a path from A1 to A2 when an electric filed is applied to the ferroelectric material. The ferroelectric material may have a first remanent polarization Pr1 or a second remanent polarization Pr2, as illustrated in FIG. 8.

On the other hand, referring to FIG. 9, the polarization hysteresis curve of the dielectric film 150 of the semiconductor memory device according to some embodiments may differ from that of FIG. 8. When an electric field is applied to the dielectric film 150, the dielectric film 150 may have a variable polarization value according to points B1 to B4 on the polarization hysteresis curve. For example, the dielectric film 150 may have a third remanent polarization Pr3 at point B1. The dielectric film 150 may have a zero (0) polarization value at point B2. The dielectric film 150 may have a fourth remanent polarization Pr4 at point B3. The dielectric film 150 may have a zero (0) polarization value at point B4.

The polarization hysteresis curve of the dielectric film 150 of FIG. 9 may be a closed-curve consisting of a first curve L1 and a second curve L2. The first curve L1 and the second curve L2 may not pass through an origin point. As an electric field applied to the dielectric film 150 increases, the slope of the first curve L1 may increase, then decrease, and then increase again. As the electric field applied to the dielectric film 150 decreases, the slope of the second curve L2 may increase, then decrease, and then increase again. In other words, each of the first curve L1 and the second curve L2 may have two inflection points. For example, the first curve L1 may include a first slope at a first voltage in quadrant IV, a second slope at a second voltage in the quadrant IV or quadrant I, and a third slope at a third voltage in the quadrant I. The second curve L2 may include a fourth slope at a fourth voltage in quadrant II, a fifth slope at a fifth voltage in the quadrant II or quadrant III, and a sixth slope at a sixth voltage in the quadrant III. The second voltage may be higher than the first voltage, and the third voltage may be higher than the first and second voltages. The fifth voltage may be lower than the fourth voltage, and the sixth voltage may be lower than the fourth and fifth voltages. The meanings of “higher” and “lower” herein may not indicate numerical values (absolute values). For example, 2V is higher than 1V and −2V is lower than −1V. The second slope may be less than the first slope. The third slope may be greater than the second slope. The fifth slope may be less than the fourth slope. The sixth slope may be greater than the fifth slope. The polarization hysteresis curve of the dielectric film 150 may be similar to an intermediate value between a polarization hysteresis curve of a ferroelectric material and a polarization hysteresis curve of an antiferroelectric material.

A relationship between remanent polarization and transient in FeFET and THE-FET will be described with reference to FIG. 10. FeFET may correspond to a semiconductor memory device including a ferroelectric material. THF-FET may correspond to a semiconductor memory device including the dielectric film 150 of the present disclosure. A material included in FeFET may have polarization voltage characteristics shown in FIG. 8. A material included in THF-FET may have polarization voltage characteristics shown in FIG. 9. At the same remnant polarization, a transient value may be lower in THF-FET than in FeFET. This means that the THF-FET may have a lower electric field applied to the interfacial film 133 than the FeFET when the semiconductor memory device operates. Therefore, in the case of a semiconductor memory device using the dielectric film 150 of the present disclosure, durability of the interfacial film 133 may be improved as the electric field applied to the interfacial film 133 decreases. That is, reliability and durability of the semiconductor memory device may be improved.

Referring back to FIGS. 1 to 7, in some embodiments, the channel structure CH may further include a filler pattern 134. The filler pattern 134 may be formed to fill the inside of the semiconductor pattern 130. The filler pattern 134 may include an insulating material, such as silicon oxide, but is not limited thereto.

In some embodiments, the channel structure CH may further include a channel pad 136. The channel pad 136 may be on (e.g., upper surface of) the semiconductor pattern 130. The channel pad 136 may be formed to be connected to the top (e.g., upper surface) of the semiconductor pattern 130. The channel pad 136 may include, for example, polysilicon doped with impurities, but is not limited thereto.

In some embodiments, a plurality of channel structures CH may be arranged in a zigzag fashion. For example, as illustrated in FIG. 3, the channel structures CH may be arranged in a staggered manner in the first and second directions X and Y that are parallel to the upper surface of the cell substrate 100. By arranging the channel structures CH in a zigzag fashion, the integration density of the semiconductor device may be increased. In some embodiments, the plurality of channel structures CH may be arranged in a honeycomb shape.

In some embodiments, dummy channel structures DCH may be formed in the mold structures MS1 and MS2 of the extension region EXT. The dummy channel structures DCH may be formed in a similar shape to that of the channel structures CH to reduce stress exerted on the mold structures MS1 and MS2 in the extension region EXT.

In some embodiments, a first source structure 102 and 104 may be formed on the cell substrate 100. The first source structure 102 and 104 may be interposed between the cell substrate 100 and the mold structures MS1 and MS2. For example, the first source structure 102 and 104 may extend along the upper surface of the cell substrate 100. The first source structure 102 and 104 may be formed to be connected to the semiconductor pattern 130 of the channel structure CH. For example, as illustrated in FIG. 5, the first source structure 102 and 104 may penetrate through the interfacial film 133 and the dielectric film 150 and be, at least partially, in contact with the semiconductor pattern 130. The first source structure 102 and 104 may be provided as a common source line (e.g., common source line CSL of FIG. 2) of the semiconductor memory device. The first source structure 102 and 104 may include, for example, polysilicon doped with impurities, or metal, but are not limited thereto. The term “penetrate through” may also mean “at least partially penetrate” hereinafter.

In some embodiments, a portion (e.g., semiconductor pattern 130 and filler pattern 134) of the channel structure CH may penetrate through the first source structure 102 and 104 in the third direction Z. For example, a lower portion of the portion of the channel structure CH may penetrate through the first source structure 102 and 104 in the third direction Z and be disposed in the cell substrate 100.

In some embodiments, the first source structure 102 and 104 may be formed as a multilayer film. For example, the first source structure 102 and 104 may include a first source layer 102 and a second source layer 104 sequentially stacked on the cell substrate 100. The first source layer 102 and the second source layer 104 may each include polysilicon doped with impurities or undoped polysilicon, but are not limited thereto. The first source layer 102 may be in contact with the semiconductor pattern 130 and provided as a common source line (e.g., common source line CSL of FIG. 2) of the semiconductor memory device. The second source layer 104 may be used as a support layer to prevent a mold stack (e.g., mold structures MS1 and MS2) from collapsing or falling in the replacement process for forming the first source layer 102.

Although not illustrated, a base insulating film may be interposed between the cell substrate 100 and the first source structure 102 and 104. The base insulating film may include, for example, silicon oxide, silicon nitride, and/or silicon oxynitride, but is not limited thereto.

In some embodiments, the first source structure 102 and 104 may not be formed in the extension region EXT in which the insulating substrate 101 is formed. Although an upper surface of the insulating substrate 101 is shown as being coplanar with an upper surface of the first source structure 102 and 104, this is merely an example. In some examples, the upper surface of the insulating substrate 101 may be higher than the upper surface of the first source structure 102 and 104.

In some embodiments, a source sacrificial film 103 may be formed on a portion of the cell substrate 100. For example, the source sacrificial film 103 may be formed on a portion of the cell substrate 100 in the extension region EXT. The source sacrificial film 103 may have a material having an etch selectivity with respect to the mold insulating films 110 and 115. For example, the mold insulating films 110 and 115 may include silicon oxide and the source sacrificial film 103 may include silicon nitride. The source sacrificial film 103 may be a layer that remains after a part of the first source structure 102 and 104 is replaced with the first source layer 102 during the manufacture process.

The block isolation region WCf, the first partial isolation region WC1, and the second partial isolation region WC2 may each extend in the first direction X to cut the mold structures MS1 and MS2. The block isolation region WCf may completely cut the mold structures MS1 and MS2. For example, the block isolation region WCf may continuously extend in the first direction X. The first partial isolation region WC1 and the second partial isolation region WC2 may each partially cut the mold structures MS1 and MS2. For example, the first partial isolation regions WC1 arranged in one row in the first direction X may be spaced apart from one another to partially cut the mold structures MS1 and MS2, and the second partial isolation regions WC2 arranged in one row in the first direction X may be spaced apart from one another to partially cut the mold structures MS1 and MS2.

The string isolation structure SC may extend in the first direction X to cut the string selection lines SSL1 and SSL2. For example, the string isolation structure SC formed in the first cell block BLK1 may divide each of the string selection lines SSL1 and SSL2 into a first region I and a second region II. Accordingly, the first string lines SSL1 in the first region I and the first string selection lines SSL1 in the second region II may be separated from each other and controlled independently of each other. The second string selection lines SSL2 in the first region I and the second string selection lines SSL2 in the second region II may be separated from each other and controlled independently of each other.

The string isolation structure SC may include an insulating material, for example, silicon oxide, silicon nitride, and/or silicon oxynitride, but is not limited thereto.

The bit lines BL may be formed on the mold structures MS1 and MS2. The bit lines BL may extend in the second direction Y and intersect the block isolation region WCf. In addition, the bit lines BL may extend in the second direction Y to be connected to the plurality of channel structures CH arranged in the second direction Y. For example, bit line contacts 182 connected to the top (e.g., upper surface) of the respective channel structures CH may be formed in the second interlayer insulating film 140b. The bit lines BL may be electrically connected to the channel structures CH through the bit line contacts 182.

The cell contacts 162 may be connected (e.g., electrically connected) to each of the gate electrodes ECL, GSL1, GSL2, WL11 to WL1n, WL21 to WL2n, SSL1, and SSL2. For example, the cell contacts 162 may extend in the third direction Z in the interlayer insulating films 140a and 140b to be connected (e.g., electrically connected) to each of the gate electrodes ECL, GSL1, GSL2, WL11 to WL1n, WL21 to WL2n, SSL1, and SSL2. In some embodiments, the cell contacts 162 may each have a bent portion between the first mold structure MS1 and the second mold structure MS2.

The source contacts 164 may be connected (e.g., electrically connected) to the first source structure 102 and 104. For example, the source contacts 164 may extend in the third direction Z in the interlayer insulating films 140a and 140b to be connected to the cell substrate 100. In some embodiments, the source contacts 164 may each have a bent portion between the first mold structure MS1 and the second mold structure MS2.

The through vias 166 may be disposed in the through region THR. For example, the through vias 166 may extend in the third direction Z in the mold structures MS1 and MS2 in the through region THR. In some embodiments, the through vias 166 may each have a bent portion between the first mold structure MS1 and the second mold structure MS2. Although the through vias 166 are illustrated as penetrating only through the mold structures MS1 and MS2, this is merely an example. In some examples, the through vias 166 may be disposed outside the mold structures MS1 and MS2 and may not penetrate through the mold structures MS1 and MS2.

Each of the cell contacts 162, the source contacts 164, and the through vias 166 may be connected (e.g., electrically connected) to the first wiring structures 180 on the interlayer insulating films 140a and 140b. For example, a first inter-wiring insulating film 142 may be formed on the second interlayer insulating film 140b. The first wiring structures 180 may be formed in the first inter-wiring insulating film 142. Each of the cell contacts 162, the source contacts 164, and the through vias 166 may be connected (e.g., electrically connected) to the first wiring structures 180 through the contact vias 184. Although not specifically illustrated, the first wiring structures 180 may be connected (e.g., electrically connected) to the bit lines BL.

The peripheral circuit region PERI may include a peripheral circuit board 200, peripheral circuit elements PT, and second wiring structures 260.

The peripheral circuit board 200 may be disposed below the cell substrate 100. For example, an upper surface of the peripheral circuit board 200 may face the lower surface of the cell substrate 100. The peripheral circuit board 200 may include, as non-limiting examples, a semiconductor substrate such as a silicon substrate, a germanium substrate, or a silicon-germanium substrate. In some embodiments, the peripheral circuit board 200 may include a silicon-on-insulator (SOI) substrate, a germanium-on-insulator (GOI) substrate, or the like.

The peripheral circuit elements PT may be formed on the peripheral circuit board 200. The peripheral circuit elements PT may configure a peripheral circuit (e.g., the peripheral circuit 30 of FIG. 1) that controls the operation of the semiconductor memory device. For example, the peripheral circuit elements PT may include a control logic (e.g., the control logic 37 of FIG. 1), a row decoder (e.g., the row decoder 33 of FIG. 1), a page buffer (e.g., the page buffer 35 of FIG. 1). In the following description, a surface of the peripheral circuit board 200 on which the peripheral circuit elements PT are disposed may be referred to as a front side of the peripheral circuit board 200. A surface of the peripheral circuit board 200 opposite to the front side of the peripheral circuit board 200 may be referred to as a back side of the peripheral circuit board 200.

The peripheral circuit elements PT may include, for example, transistors, but are not limited thereto. The peripheral circuit elements PT may include, for example, various active elements such as transistors, and/or various passive elements such as capacitors, resistors, or inductors.

In some embodiments, the back side of the cell substrate 100 may face the front side of the peripheral circuit board 200. For example, a second inter-wiring insulating film 240 on (e.g., covering) the peripheral circuit elements PT may be formed on the front side of the peripheral circuit board 200. The cell substrate 100 and/or the insulating substrate 101 may be stacked on an upper surface of the second inter-wiring insulating film 240.

The first wiring structures 180 may be connected (e.g., electrically connected) to the peripheral circuit elements PT through the through vias 166. For example, the second wiring structures 260 connected (e.g., electrically connected) to the peripheral circuit elements PT may be formed in the second inter-wiring insulating film 240. The through vias 166 may extend in the third direction Z to connect (e.g., electrically connect) the first wiring structures 180 to the second wiring structures 260. Accordingly, the bit lines BL, each of the gate electrodes ECL, GSL1, GSL2, WL11 to WL1n, WL21 to WL2n, SSL1, and SSL2 and/or the first source structure 102 and 104 may be electrically connected to the peripheral circuit elements PT.

In some embodiments, the through vias 166 may penetrate through the insulating substrate 101 to connect (e.g., electrically connect) the first wiring structures 180 to the second wiring structures 260. Accordingly, the through vias 166 may be electrically isolated from the cell substrate 100.

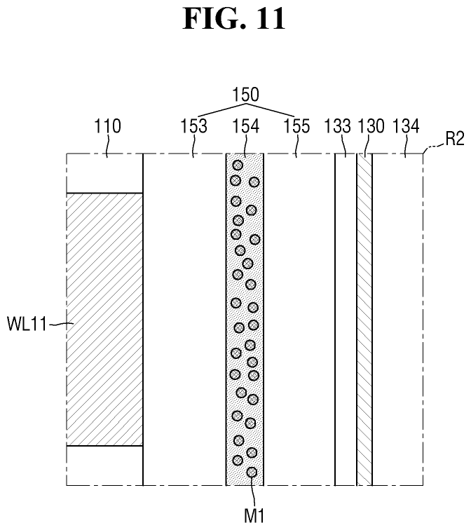

FIG. 11 is a view for explaining a semiconductor memory device according to some embodiments. For ease of description, differences from the embodiments of FIGS. 1 to 10 will be mainly described.

Referring to FIG. 11, in some embodiments, a semiconductor memory device may include a dielectric film 150. The dielectric film 150 may include a third crystalline film 153, a fourth crystalline film 155, and an amorphous film 154.

The fourth crystalline film 155 may be disposed on an interfacial film 133. The fourth crystalline film 155 may extend along outer side surfaces of the interfacial film 133. The third crystalline film 153 may be disposed on the interfacial film 133. The third crystalline film 153 may be disposed on the fourth crystalline film 155. In one embodiment, the fourth crystalline film 155 may include, for example, hafnium oxide (HfO₂), zirconium oxide (ZrO₂), hafnium zirconium oxide (HfZrO₂), vanadium oxide (VO₂), aluminum oxide (Al₂O₃), and/or silicon oxide (SiO₂). In some embodiments, the fourth crystalline film 155 may include the same matrix and impurities as those of the first crystalline film 151 or the second crystalline film 152 of FIG. 6.

The amorphous film 154 may be disposed between the third crystalline film 153 and the fourth crystalline film 155. The amorphous film 154 may be in contact with the third crystalline film 153 and the fourth crystalline film 155. The amorphous film 154 may extend along outer side surfaces of the fourth crystalline film 155. The amorphous film 154 may include hafnium oxide and/or zirconium oxide, but is not limited thereto. The hafnium oxide and zirconium oxide (or other similar materials) may be a matrix of the amorphous film 154. The amorphous film 154 may include a first material M1. The first material M1 may be dispersed and positioned in the amorphous film 154. The concentration of the first material M1 may be 50% or more of the amorphous film 154. The first material M1 may include aluminum oxide (Al₂O₃) and/or silicon oxide (SiO₂), but is not limited thereto.

The third crystalline film 153 may be disposed on the amorphous film 154. The third crystalline film 153 may extend along outer side surfaces of the amorphous film 154. The third crystalline film 153 may be disposed between the interfacial film 133 and each of the gate electrodes ECL, GSL1, GSL2, WL11 to WL1n, WL21 to WL2n, SSL1, and SSL2 and each of the mold insulating films 110 and 115. The third crystalline film 153 may be in contact with each of the gate electrodes ECL, GSL1, GSL2, WL11 to WL1n, WL21 to WL2n, SSL1, and SSL2. In one embodiment, the third crystalline film 153 may include, for example, hafnium oxide (HfO₂), zirconium oxide (ZrO₂), hafnium zirconium oxide (HfZrO₂), vanadium oxide (VO₂), aluminum oxide (Al₂O₃), and/or silicon oxide (SiO₂), but is not limited thereto. In some embodiments, the third crystalline film 153 may include the same matrix and impurities as those of the first crystalline film 151 or the second crystalline film 152 of FIG. 6.

The third crystalline film 153, the amorphous film 154, and the fourth crystalline film 155 in unison may have voltage-polarization characteristics similar to or same as those of the dielectric film 150 of FIG. 6. A voltage-polarization curve for the third crystalline film 153, the amorphous film 154, and the fourth crystalline film 155 in unison may be the same as that of FIG. 9.

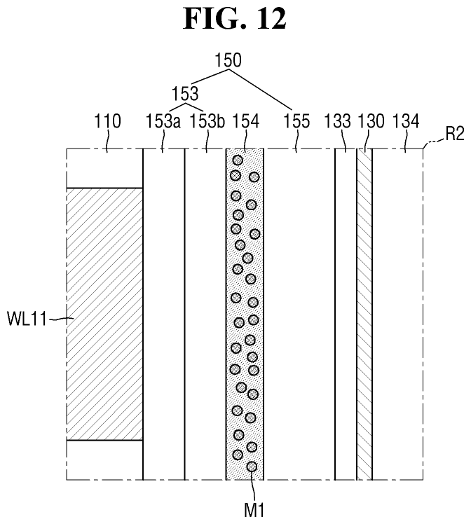

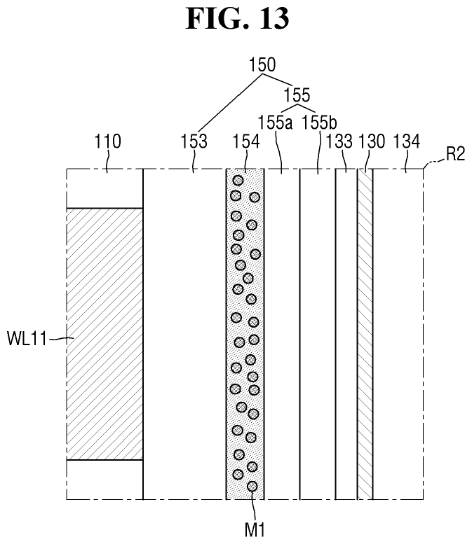

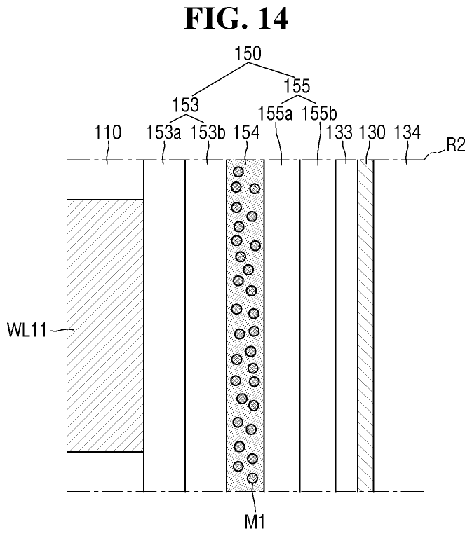

FIG. 12 is a view for explaining a semiconductor memory device according to some embodiments. FIG. 13 is a view for explaining a semiconductor memory device according to some embodiments. FIG. 14 is a view for explaining a semiconductor memory device according to some embodiments. For ease of description, differences from the embodiments of FIGS. 1 to 11 will be mainly described.

Referring to FIG. 12, the third crystalline film 153 may include a first sub-crystalline film 153a and a second sub-crystalline film 153b. The first sub-crystalline film 153a and the second sub-crystalline film 153b may be sequentially disposed on (e.g., an outer side surface of) the amorphous film 154. In one example, the first sub-crystalline film 153a may include a ferroelectric material and the second sub-crystalline film 153b may include an antiferroelectric material. In some examples, the first sub-crystalline film 153a may include an antiferroelectric material and the second sub-crystalline film 153b may include a ferroelectric material.

Referring to FIG. 13, the fourth crystalline film 155 may include a third sub-crystalline film 155a and a fourth sub-crystalline film 155b. The third sub-crystalline film 155a and the fourth sub-crystalline film 155b may be sequentially disposed on the amorphous film 154. The third sub-crystalline film 155a and the fourth sub-crystalline film 155b may be disposed between the amorphous film 154 and the interfacial film 133. In one example, the third sub-crystalline film 155a may include a ferroelectric material and the fourth sub-crystalline film 155b may include an antiferroelectric material. In some examples, the third sub-crystalline film 155a may include an antiferroelectric material and the fourth sub-crystalline film 155b may include a ferroelectric material.

Referring to FIG. 14, the third crystalline film 153 may include a first sub-crystalline film 153a and a second sub-crystalline film 153b. The fourth crystalline film 155 may include a third sub-crystalline film 155a and a fourth sub-crystalline film 155b. Descriptions of the first to fourth sub-crystalline films 153a, 153b, 155a, and 155b may be the same as those of FIGS. 12 and 13.

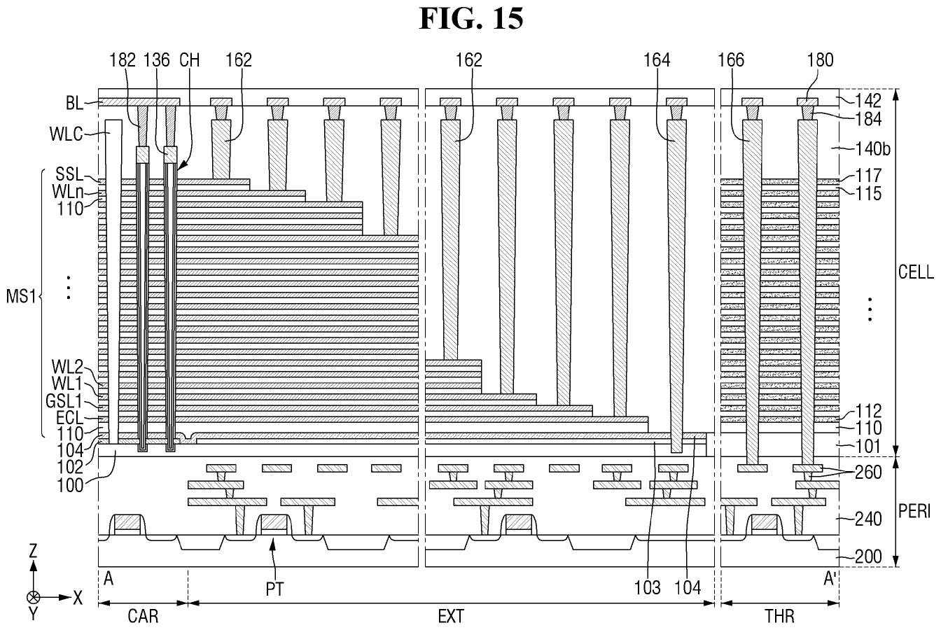

FIG. 15 is a view for explaining a semiconductor memory device according to some embodiments. For ease of description, differences from the embodiments of FIGS. 1 to 10 will be mainly described.

Referring to FIG. 15, a semiconductor memory device according to some embodiments may include a first mold structure MS1 only. That is, the semiconductor memory device according to some embodiments may have a single stack structure. Channel structures CH, cell contacts 162, source contacts 164, and through vias 166 may not have a bent portion.

Hereinafter, an electronic system including a semiconductor memory device according to example embodiments will be described with reference to FIGS. 1 to 15.

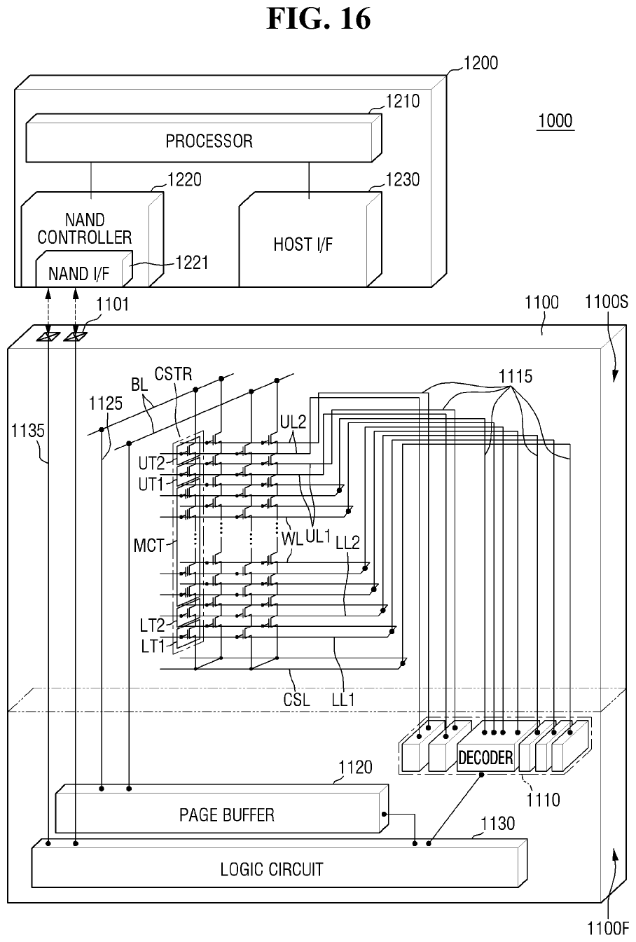

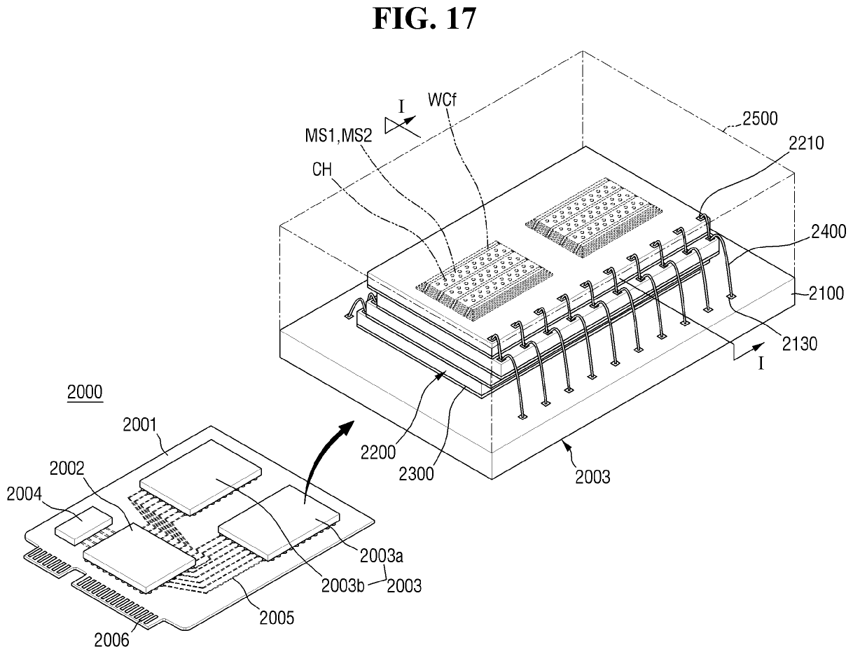

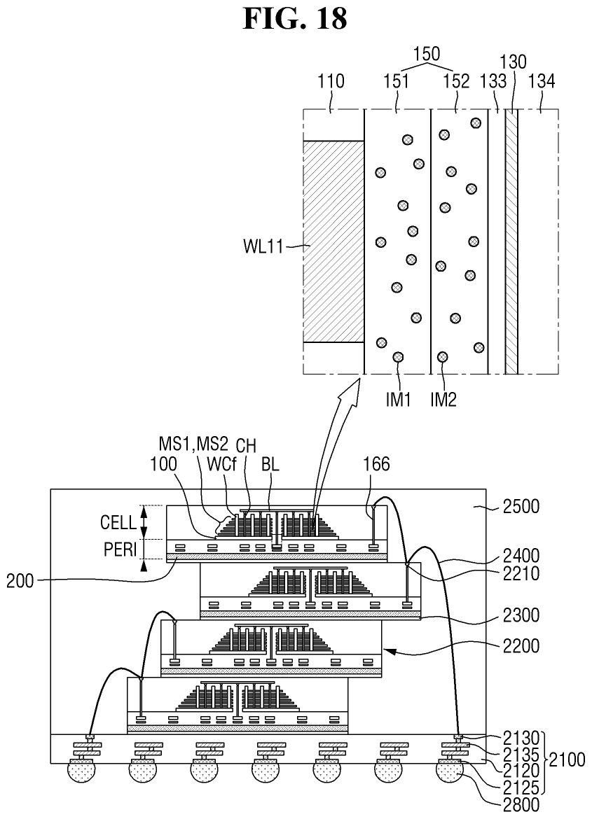

FIG. 16 is an example block diagram illustrating an electronic system according to some embodiments. FIG. 17 is an example perspective view illustrating an electronic system according to some embodiments. FIG. 18 is a schematic cross-sectional view taken along line I-I′ of FIG. 17 and an enlarged view of a portion thereof.

Referring to FIG. 16, an electronic system 1000 according to some embodiments may include a semiconductor memory device 1100 and a controller 1200 electrically connected to the semiconductor memory device 1100. The electronic system 1000 may be a storage device that includes one or a plurality of semiconductor memory devices 1100, or may be an electronic device that includes the storage device. For example, the electronic system 1000 may be a solid state drive (SSD) device including one or a plurality of semiconductor memory devices 1100, a universal serial bus (USB) device, a computing system, a medical device, and/or a communication device, but is not limited thereto.

The semiconductor memory device 1100 may be a non-volatile memory device (e.g., a NAND flash memory device), and may be, for example, the semiconductor memory device described above with respect to FIGS. 1 to 15. The semiconductor memory device 1100 may include a first structure 1100F, and a second structure 11005 on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1).

The second structure 11005 may include the common source line CSL, the plurality of bit lines BL, and the plurality of cell strings CSTR described above with reference to FIG. 2. The cell strings CSTR may be connected (e.g., electrically connected) to the decoder circuit 1110 through at least one word line WL, at least one string selection line SSL, and at least one ground selection line GSL. Further, the cell strings CSTR may be connected (e.g., electrically connected) to the page buffer 1120 through the bit lines BL.

In some embodiments, the common source line CSL and the cell strings CSTR may be electrically connected to the decoder circuit 1110 through first connection wirings 1115 that extend from the first structure 1100F to the second structure 11005. The first connection wirings 1115 may correspond to the through vias 166 described above with reference to FIGS. 1 to 15. That is, the through vias 166 may electrically connect the respective gate electrodes ECL, GSL, WL, and SSL (e.g., gate electrodes ECL, GSL1, GSL2, WL11 to WL1n, WL21 to WL2n, SSL1, and SSL2 of FIG. 2) to the decoder circuit 1110 (e.g., the row decoder 33 of FIG. 1).

In some embodiments, the bit lines BL may be electrically connected to the page buffer 1120 through second connection wirings 1125 that extend from the first structure 1100F to the second structure 11005. The second connection wirings 1125 may correspond to the through vias 166 described above with reference to FIGS. 1 to 15. That is, the through vias 166 may electrically connect the bit lines BL to the page buffer 1120 (e.g., the page buffer 35 of FIG. 1).

The semiconductor memory device 1100 may communicate with the controller 1200 through at least one input/output (I/O) pad 1101 that is electrically connected to the logic circuit 1130 (e.g., the control logic 37 of FIG. 1). The I/O pad 1101 may be electrically connected to the logic circuit 1130 through an I/O connection wiring 1135 that extends from the first structure 1100F to the second structure 11005.

The controller 1200 may include a processor 1210, a NAND controller 1220, and a host interface 1230. In some embodiments, the electronic system 1000 may include a plurality of semiconductor memory devices 1100, and in this case, the controller 1200 may control the plurality of semiconductor memory devices 1100. As described above, the semiconductor memory device 1100 may be the semiconductor memory device described above with respect to FIGS. 1 to 15 and may not be a NAND flash memory device. In that case, the NAND controller 1220 may correspond to a semiconductor memory device controller for the semiconductor memory device described above with respect to FIGS. 1 to 15.

The processor 1210 may control the overall operation of the electronic system 1000 including the controller 1200. The processor 1210 may operate according to predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When receiving the control command from an external host through the host interface 1230, the processor 1210 may control the semiconductor memory device 1100 in response to the control command. As described above, the semiconductor memory device 1100 may be the semiconductor memory device described above with respect to FIGS. 1 to 15 and may not be a NAND flash memory device. In that case, the NAND interface 1221 may correspond to a semiconductor memory device controller interface for the semiconductor memory device described above with respect to FIGS. 1 to 15.

Referring to FIGS. 17 and 18, an electronic system 2000 according to some embodiments may include a main board 2001, a main controller 2002 mounted on the main board 2001, one or more semiconductor packages 2003, and a dynamic random-access memory (DRAM) 2004. The semiconductor package 2003 and the DRAM 2004 may be connected (e.g., electrically connected) to the main controller 2002 by wiring patterns 2005 formed on the main board 2001.

The main board 2001 may include a connector 2006 including a plurality of pins coupled to an external host. In the connector 2006, the number and arrangement of the plurality of pins may vary depending on the communication interface between the electronic system 2000 and the external host. In some embodiments, the electronic system 2000 may communicate with an external host according to interfaces such as USB, peripheral component interconnect express (PCI-Express), serial advanced technology attachment (SATA), and/or M-Phy for universal flash storage (UFS), but is not limited thereto. In some embodiments, the electronic system 2000 may be operated by power supplied from an external host through the connector 2006. The electronic system 2000 may further include a power management integrated circuit (PMIC) that distributes the power supplied from the external host to the main controller 2002 and the semiconductor package 2003.

The main controller 2002 may record data in the semiconductor package 2003 and/or read data from the semiconductor package 2003, and may improve the operating speed of the electronic system 2000.

The DRAM 2004 may be a buffer memory configured to alleviate a speed difference between the semiconductor package 2003, which is a data storage area, and an external host. The DRAM 2004 included in the electronic system 2000 may also operate as a type of cache memory, and may also provide a space for temporarily storing data in the control operation of the semiconductor package 2003. When the DRAM 2004 is included in the electronic system 2000, the main controller 2002 may further include a DRAM controller for controlling the DRAM 2004, in addition to the semiconductor package controller (e.g., NAND controller) for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may each be a semiconductor package that includes a plurality of semiconductor chips 2200. The first semiconductor package 2003a and the second semiconductor package 2003b may each include a package substrate 2100, semiconductor chips 2200 on the package substrate 2100, adhesive layers 2300 placed on the lower surfaces of each of the semiconductor chips 2200, a connection structure 2400 that is configured to electrically connect the semiconductor chips 2200 to the package substrate 2100, and a molding layer 2500 that covers the semiconductor chips 2200 and the connection structure 2400 on the package substrate 2100.

The package substrate 2100 may be a printed circuit board that includes upper pads 2130. Each semiconductor chip 2200 may include an I/O pad 2210. The I/O pad 2210 may correspond to the I/O pad 1101 of FIG. 16.

In some embodiments, the connection structure 2400 may be a bonding wire that electrically connects the I/O pad 2210 to the upper pads 2130. Therefore, in each of the first semiconductor package 2003a and the second semiconductor package 2003b, the semiconductor chips 2200 may be electrically connected to each other in a bonding wire manner, and may be electrically connected to the upper pads 2130 of the package substrate 2100. In some embodiments, in each of the first semiconductor package 2003a and the second semiconductor package 2003b, the semiconductor chips 2200 may also be electrically connected to each other by a connection structure including a through silicon via (TSV) instead of the bonding wire type connection structure 2400.

In some embodiments, the main controller 2002 and the semiconductor chips 2200 may be included in a single package. In some embodiments, the main controller 2002 and the semiconductor chips 2200 may be mounted on a separate interposer board different from the main board 2001, and the main controller 2002 and the semiconductor chips 2200 may be connected (e.g., electrically connected) to each other by the wiring formed on the interposer board.

In some embodiments, the package substrate 2100 may be a printed circuit board. The package substrate 2100 may include a package substrate body portion 2120, upper pads 2130 placed on an upper surface of the package substrate body portion 2120, lower pads 2125 placed on a lower surface of the package substrate body portion 2120 or exposed through the lower surface, and inner wirings 2135 that electrically connect the upper pads 2130 to the lower pads 2125 inside the package substrate body portion 2120. The upper pads 2130 may be electrically connected to the connection structures 2400. The lower pads 2125 may be connected (e.g., electrically connected) to the wiring patterns 2005 of the main board 2001 of the electronic system 2000 through conductive connections 2800, as seen in FIG. 17.

In the electronic system according to some embodiments, each semiconductor chip 2200 may include the semiconductor memory device described above with reference to FIGS. 1 to 15. For example, each semiconductor chip 2200 may include a peripheral circuit region PERI and a memory cell region CELL stacked on the peripheral circuit region PERI. For example, the peripheral circuit region PERI may include the peripheral circuit board 200 and the second wiring structure 260 described above with reference to FIGS. 3 to 7. Also, for example, the memory cell region CELL may include the cell substrate 100, the mold structures MS1 and MS2, and the channel structures CH described above with reference to FIGS. 3 to 7.

For simplicity and clarity of illustration, elements in the drawings may not be necessarily drawn to scale. The same reference numbers in different drawings may represent the same or similar elements, and as such may perform similar functionality. Further, descriptions and details of well-known steps and elements may be omitted for simplicity of the description. Furthermore, in the detailed description of the present disclosure, numerous specific details are set forth in order to provide a thorough understanding of the present disclosure. However, it will be understood that the present disclosure may be practiced without these specific details. In other instances, well-known methods, procedures, components, and circuits may not be described in detail so as not to unnecessarily obscure aspects of the present disclosure. It will be understood that the description herein is not intended to limit the claims to the specific embodiments described. On the contrary, it is intended to cover alternatives, modifications, and equivalents as may be included within the scope of the present disclosure as defined by the appended claims.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify an entirety of list of elements and may not modify the individual elements of the list. When referring to “C to D”, this means C inclusive to D inclusive unless otherwise specified.

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described above could be termed a second element, component, region, layer or section, without departing from the scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is disposed “directly on” or “directly on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is disposed “directly below” or “directly under” another layer, film, region, plate, or the like, the former directly contacts the latter and still another layer, film, region, plate, or the like is not disposed between the former and the latter.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence. Moreover, the function or operation in the specific block (e.g., step) may be separated into multiple blocks (e.g., steps) and/or may be at least partially integrated.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

In concluding the detailed description, those skilled in the art will appreciate that many variations and modifications may be made to the embodiments described herein without substantially departing from the principles of the present inventive concept. Therefore, the disclosed embodiments of the invention are used in a generic and descriptive sense only and not for purposes of limitation.

What is claimed:

1. A semiconductor memory device comprising:
a substrate;
a mold structure including a plurality of gate electrodes and a plurality of mold insulating films alternately stacked on the substrate; and
a channel structure that penetrates the mold structure,
wherein the channel structure comprises:
a semiconductor pattern; and
a dielectric film on the semiconductor pattern,
wherein the dielectric film comprises:
a first crystalline film that is in contact with the plurality of gate electrodes; and
a second crystalline film between the first crystalline film and the semiconductor pattern,
wherein the first crystalline film includes a first matrix and a first impurity,
wherein the second crystalline film includes a second matrix and a second impurity,
wherein each of the first matrix and the second matrix comprises at least one of HfO₂, HfₓZr₁₋ₓO₂ (0.5<x<1), and Hf_{1-y}Zr_{y}O₂ (0.5<y<1), and
wherein each of the first impurity and the second impurity has a concentration of 10 at % (atomic percent) or less of the first crystalline film and the second crystalline film, respectively.

2. The semiconductor memory device of claim 1, wherein the first matrix includes a different material from that of the second matrix.

3. The semiconductor memory device of claim 1, wherein each of the first impurity and the second impurity comprises Al₂O₃, SiO₂, Y₂O₃, Er₂O₃, Lu₂O₃, Gd₂O₃, Ta₂O₅, MgO, SiC, AlN, and/or Mo.

4. The semiconductor memory device of claim 3, wherein the first impurity includes a different material from that of the second impurity.

5. The semiconductor memory device of claim 3, wherein the first impurity and the second impurity include a same material.

6. The semiconductor memory device of claim 1, wherein a polarization-hysteresis curve (P-V curve) of the dielectric film comprises a first curve and a second curve,
wherein the first curve has a first slope at a first voltage in quadrant IV, a second slope at a second voltage in the quadrant IV or quadrant I, and a third slope at a third voltage in the quadrant I,
wherein the second curve has a fourth slope at a fourth voltage in quadrant II, a fifth slope at a fifth voltage in the quadrant II or quadrant III, and a sixth slope at a sixth voltage in the quadrant III,
wherein the second voltage is higher than the first voltage, and the third voltage is higher than the first and second voltages,
wherein the fifth voltage is lower than the fourth voltage, and the sixth voltage is lower than the fourth and fifth voltages,
wherein the second slope is less than the first slope, and the third slope is greater than the second slope,
wherein the fifth slope is less than the fourth slope, and the sixth slope is greater than the fifth slope, and
wherein the first curve and the second curve are spaced apart from an origin point.

7. The semiconductor memory device of claim 1, wherein the first crystalline film comprises a ferroelectric material and the second crystalline film comprises an antiferroelectric material.

8. The semiconductor memory device of claim 1, wherein the dielectric film further comprises an amorphous film between the first crystalline film and the second crystalline film.

9. The semiconductor memory device of claim 1, wherein a thickness of the dielectric film is 150 angstroms (Å) or less in a first direction parallel to an upper surface of the substrate.

10. The semiconductor memory device of claim 1, further comprising an interfacial film between the dielectric film and the semiconductor pattern.

11. The semiconductor memory device of claim 10, wherein the interfacial film comprises silicon oxide (SiO₂).

12. The semiconductor memory device of claim 1, further comprising a source layer in contact with the semiconductor pattern.

13. A semiconductor memory device comprising:
a substrate;
a mold structure including a plurality of gate electrodes and a plurality of mold insulating films alternately stacked on the substrate; and
a channel structure that penetrates the mold structure,
wherein the channel structure comprises:
a semiconductor pattern;
an interfacial film on the semiconductor pattern;
a first crystalline film on the interfacial film;
a second crystalline film on the first crystalline film and in contact with the plurality of gate electrodes; and
an amorphous film between the first crystalline film and the second crystalline film,
wherein the interfacial film is between the semiconductor pattern and the first crystalline film,
wherein the first crystalline film is between the second crystalline film and the semiconductor pattern,
wherein the amorphous film comprises a first material,
wherein a first matrix of the amorphous film comprises HfO₂ and/or ZrO₂, and
wherein the first material comprises Al₂O₃ and/or SiO₂.

14. The semiconductor memory device of claim 13, wherein a concentration of the first material is 50% or more of the amorphous film.

15. The semiconductor memory device of claim 13, wherein each of the first crystalline film and the second crystalline film comprises HfO₂, ZrO₂, HfZrO₂, VO₂, Al₂O₃, and/or SiO_{2.}

16. The semiconductor memory device of claim 13, wherein the first crystalline film comprises a first sub-crystalline film and a second sub-crystalline film on the first sub-crystalline film,
wherein the first sub-crystalline film comprises a ferroelectric material, and
wherein the second sub-crystalline film comprises an antiferroelectric material.

17. The semiconductor memory device of claim 16, wherein the second crystalline film comprises a third sub-crystalline film and a fourth sub-crystalline film on the third sub-crystalline film,
wherein the third sub-crystalline film comprises a ferroelectric material, and
wherein the fourth sub-crystalline film comprises an antiferroelectric material.

18. The semiconductor memory device of claim 13, wherein at least one of the first crystalline film and the second crystalline film comprises a first impurity,
wherein a concentration of the first impurity is 10 at % (atomic percent) or less, and wherein the first impurity comprises Al₂O₃, SiO₂, Y₂O₃, Er₂O₃, Lu₂O₃, Gd₂O₃, Ta₂O₅, MgO, SiC, AlN, and/or Mo.

19. An electronic system comprising:
a main board;
a semiconductor memory device on the main board; and
a controller on the main board, wherein the controller is electrically connected to the semiconductor memory device,
wherein the semiconductor memory device comprises:
a cell substrate comprising a cell array region and an extension region;
a mold structure comprising a plurality of gate electrodes that are sequentially stacked on the cell substrate and stacked in the extension region in a stepped manner; and
a channel structure that penetrates the mold structure in the cell array region,
wherein the channel structure comprises a semiconductor pattern and a dielectric film on the semiconductor pattern,
wherein the dielectric film comprises a first crystalline film and a second crystalline film between the first crystalline film and the semiconductor pattern,
wherein the first crystalline film is in contact with the plurality of gate electrodes,
wherein the first crystalline film includes a first matrix and the second crystalline film includes a second matrix,
wherein each of the first matrix and the second matrix comprises at least one of HfO₂, HfₓZr₁₋ₓO₂ (0.5<x<1), and Hf_{1-y}Zr_{y}O₂ (0.5<y<1),
wherein the first crystalline film has 10 at % (atomic percent) or less of a first impurity,
wherein the second crystalline film has 10 at % or less of a second impurity, and
wherein each of the first impurity and the second impurity comprises Al₂O₃, SiO₂, Y₂O₃, Er₂O₃, Lu₂O₃, Gd₂O₃, Ta₂O₅, MgO, SiC, AlN, and/or Mo.

20. The electronic system of claim 19, further comprising:
an amorphous film between the first crystalline film and the second crystalline film,
wherein a matrix of the amorphous film comprises HfO₂ and/or ZrO₂,
wherein the amorphous film comprises a first material,
wherein the first material comprises Al₂O₃ and/or SiO₂, and
wherein a concentration of the first material is 50% or more of the amorphous film.
